(19) United States
(12) Patent Application Publication
(10) Pub. No.: US 2007/0082494 A1
(43) Pub. Date: Apr. 12, 2007

(54) METHOD FOR FORMING SILICIDE LAYER

(75) Inventors: Yi-Wei Chen, Taichung County (TW); Yi-Yiing Chiang, Taipei City (TW); Yu-Lan Chang, Kaohsiung City (TW); Tzung-Yu Hung, Tainan County (TW); Chao-Ching Hsieh, Hsinchu Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: UNITED MICROELECTRONICS CORP., Hsinchu (TW)

(21) Appl. No.: 11/538,061

(22) Filed: Oct. 3, 2006

Related U.S. Application Data
(60) Provisional application No. 60/723,503, filed on Oct. 3, 2005.

(51) Int. Cl. C23F 1/00; H01L 21/311; B44C 1/22

(52) U.S. Cl. 438/694; 438/710; 216/67

(57) ABSTRACT

A method for forming a metal silicide over a substrate is provided. The method comprises steps of performing a fluorine-containing plasma treatment on the substrate to remove a plurality of residual over the substrate, wherein the fluorine-containing plasma treatment is performed in a first tool system. Then, a vacuum system of the first tool system is broken. The substrate is transferred from the first tool system into a second tool system. A metal silicide layer is formed over the substrate in the second tool system.

### CROSS-REFERENCE TO RELATED APPLICATION

This application claims the priority benefits of U.S. provisional application Ser. No. 60/723,503, filed on Oct. 3, 2005. All disclosure of this application is incorporated herein by reference.

### BACKGROUND OF THE INVENTION

1. Field of Invention

The present invention relates to a method for forming a semiconductor. More particularly, the present invention relates to a method for forming a silicide layer.

2. Description of Related Art

Usually, silicide is formed on the gates, the source/drain region or the interconnects to lower the contact resistance between the semiconductor devices on a substrate. Since lattice of the silicide is rearranged when it is treated by high-temperature annealing, the defects in the silicide are eliminated, wherein the defects are eliminated, and perfect grains are grown instead of defective grains. A crystalline structure is formed in the silicide after a high-temperature annealing is performed so that the resistance of the silicide is lowered. Hence, the contact resistance can be reduced by forming a silicide layer on the gates, the source/drain region or the interconnects.

Typically, before the deposition process for forming the metal silicide layer, a surface clean process is performed over the substrate to remove the impurity residual generated in the previous processes. The conventional method for cleaning the surface of the substrate is wet etching. However, the experimental data shows that the impurity residual cannot be completely removed by the wet etching process. Also, the impurity residual is the cause for generating pits between the metal silicide and the substrate. Furthermore, the pits are the leakage paths in the devices so that the yield of the devices is decreased.

### SUMMARY OF THE INVENTION

Accordingly, at least one objective of the present invention is to provide a method for forming a metal silicide over a substrate capable of preventing the metal silicide from generating pits therein.

At least another objective of the present invention is to provide a method for cleaning a surface of a substrate for a later formed metal silicide. By using the method according to the present invention, the impurity residual over the substrate can be completely removed.

To achieve these and other advantages and in accordance with the purpose of the invention, as embodied and broadly described herein, the invention provides a method for forming a metal silicide over a substrate. The method comprises steps of performing a fluorine-containing plasma treatment on the substrate to remove a plurality of residual over the substrate, wherein the fluorine-containing plasma treatment is performed in a first tool system. Then, a vacuum system of the first tool system is broken. The substrate is transferred from the first tool system into a second tool system. A metal silicide layer is formed over the substrate in the second tool system.

According to one embodiment of the present invention, before the metal silicide layer is formed, a soft clean process is performed on the substrate.

According to one embodiment of the present invention, the soft clean process is performed by using an inert-gas plasma.

According to one embodiment of the present invention, the inert-gas plasma includes an argon-gas plasma.

According to one embodiment of the present invention, the soft clean process is performed in the second tool system.

According to one embodiment of the present invention, the fluorine-containing plasma treatment is selected from a group consisting of NF₃ plasma, NF₃/NH₃ plasma, NF₃/H₂ plasma and SF₆/H₂O plasma.

According to one embodiment of the present invention, the fluorine-containing plasma treatment is performed at a pressure of about 30 mTorr with a power of about 20˜300 Watt.

According to one embodiment of the present invention, the flow rate of a fluorine-containing gas of the fluorine-containing plasma treatment is about 5˜25 sccm.

According to one embodiment of the present invention, the metal silicide is made of cobalt silicide.

The present invention further provides a method for cleaning a surface of a substrate before a silicidation process is performed over the substrate. The method comprises steps of performing a dry clean process in an etching tool system and then performing a soft clean process in a deposition tool system. The silicidation process is going to be performed on the substrate in the deposition tool system.

According to one embodiment of the present invention, the dry clean process is performed by a fluorine-containing plasma.

According to one embodiment of the present invention, the fluorine-containing plasma is selected from a group consisting of NF₃ plasma, NF₃/NH₃ plasma, NF₃/H₂ plasma and SF₆/H₂O plasma.

According to one embodiment of the present invention, the fluorine-containing plasma is performed at a pressure of about 30 mTorr with a power of about 20˜300 Watt.

According to one embodiment of the present invention, the flow rate of a fluorine-containing gas of the fluorine-containing plasma is about 5˜25 sccm.

According to one embodiment of the present invention, before the soft clean process and after the dry clean process, the method further comprise steps of breaking a vacuum system of the etching tool system and then transferring the substrate from the etching tool system into the deposition tool system.

In the present invention, the dry clean process with the use of the fluorine-containing plasma removes not only the polymer and oxide on the substrate but also remove a portion of the silicon of the substrate so that the surface of the substrate is clean for later formed metal layer. Furthermore, the fluorine-containing plasma can repair silicon dangling bonds, which is one of the reasons to generate the pits in the metal silicide layer, on the surface of the substrate. In addition, since the dry clean process is performed in a tool system different from that for performing the deposition process of the metal layer, the impurity residual etched away from the substrate does not contaminate the wall of the tool system for performing the deposition process. Also, before the deposition process is performed, a soft clean with the operation power smaller than that of the dry clean process is performed to remove the possible oxide generated during the transferring procedure so that the surface of the substrate can be completely cleaned.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a process flow diagram, schematically illustrating a method for forming a metal silicide over a substrate according to one embodiment of the present invention.

FIG. 2 is a process flow showing a method for forming the metal silicide layer.

### DESCRIPTION OF EMBODIMENTS

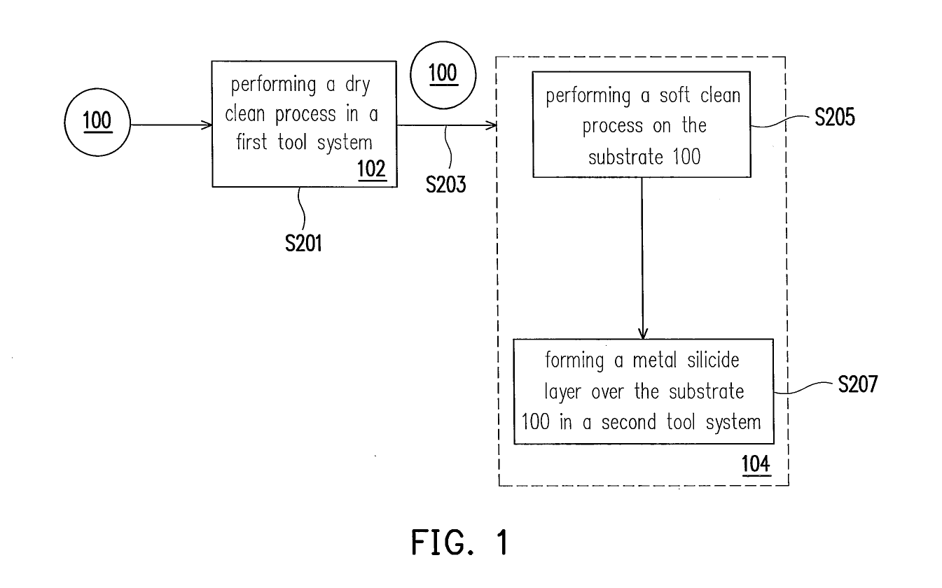

FIG. 1 is a process flow diagram, schematically illustrating a method for forming a metal silicide over a substrate according to one embodiment of the present invention. As shown in FIG. 1, a substrate 100 having devices formed thereon is provided. The devices can be a metal-oxide semiconductor composed of a gate and a source/drain region adjacent to the gate, for example. Thereafter, in the step S201, a dry clean process is performed on the substrate 100. It should be noticed that the dry clean process is performed in a first tool system 102. The first tool system 102 can be, for example, an etching tool system. The purpose for performing the dry clean process is to remove the residual over the substrate 100 after the devices are formed. The residual can be the manufacturing by-product such as polymer, oxide or implant species residual. Furthermore, the dry clean process can be a fluorine-containing plasma treatment. That is, the dry clean process is performed by using a fluorine-containing plasma. Moreover, the fluorine-containing plasma can be selected from a group consisting of NF₃ plasma, NF₃/NH₃ plasma, NF₃/H₂ plasma and SF₆/H₂O plasma. Also, the fluorine-containing plasma is performed at a pressure of about 30 mTorr with an operation power of about 20˜300 Watt. Further, the flow rate of the fluorine-containing gas for generating the fluorine-containing plasma is about 5˜25 sccm.

Then, in the step S203, the substrate 100 is transferred from the first tool system 102 in to a second tool system 104. During the step S203, the vacuum system of the first tool system 102 is broken and then the substrate 100 is transferred into the second tool system 104 in which a metal silicide layer are going to be formed over the substrate 100. Furthermore, the second tool system 104 can be, for example, a deposition tool system.

Before the metal silicide layer is formed over the substrate 100, a soft clean process (step S205) is performed on the substrate 100 for further removing the oxide impurity generated during the transferring procedure. The soft clean process can be performed in the deposition tool system 104 as shown in FIG. 1. Furthermore, the soft clean process can be performed by using an inert-gas plasma such as an argon-gas plasma. In addition, the operation power for performing the soft clean process is smaller than that of the dry clean process. Also, the flow rate of the argon gas of the soft clean process is about 0˜10 sccm and the soft clean process is performed for about 5˜20 seconds.

Thereafter, in the step S207, a metal silicide layer is formed over the substrate 100 in the second tool system. The metal silicide layer can be, for example, made of cobalt silicide.

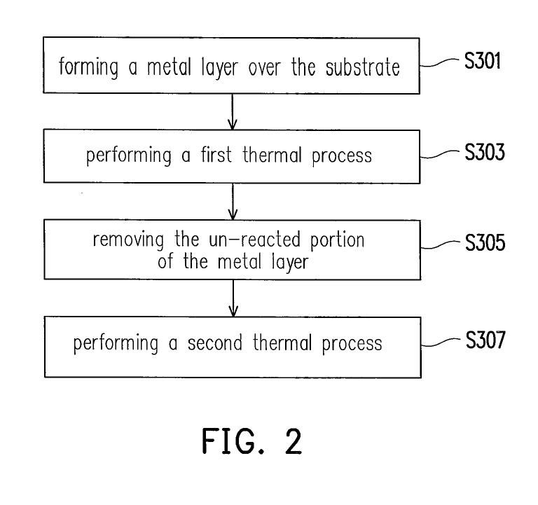

FIG. 2 is a process flow showing a method for forming the metal silicide layer. Taking metal cobalt as an example, the method for forming the metal silicide layer (step S207 in FIG. 1) is detail described herein. As shown in FIG. 2, in the step S301, a metal layer, such as a cobalt layer, is formed over the substrate 100. The method of forming the metal layer can be performed by a conventional method known to the skilled in the art. In this example, the metal layer is formed by sputtering.

Then, in the step S303, a first thermal process is used to convert portions of the metal layer above the gate electrodes and the source/drain regions of the devices into a metal silicide layer. In this embodiment, the metal silicide layer can be, for example, made of cobalt silicide. The remaining metal layer, which is not converted into the metal silicide layer, is removed to expose the metal silicide layer (step S305). The method of removing the metal layer can be performed by a conventional method known to the skilled in the art. In this example, the removal of the metal layer is by wet etching.

Thereafter, in the step S307, a second thermal process is performed to convert the metal silicide layer, such as the cobalt silicide layer, into a CoSi₂ layer. In the conventional process for forming the metal silicide over a substrate, the substrate is pre-cleaned by using the wet etching process. However, the impurity residual, such as the polymer by-product or oxide cannot be completely removed. Hence, after the second thermal process is performed on the substrate to convert the cobalt silicide into CoSi₂, the impurity residual would lead to pits at the boundary between CoSi₂ and the substrate. Therefore, the pits become the cause of the leakage path and the device yield is decreased. In the present invention, the dry clean process with the use of the fluorine-containing plasma removes not only the polymer and oxide on the substrate but also remove a portion of the silicon of the substrate so that the surface of the substrate is clean for later formed metal layer. Furthermore, the fluorine-containing plasma can repair silicon dangling bonds, which is one of the reasons to generate the pits in CoSi₂, on the surface of the substrate. In addition, since the dry clean process is performed in a tool system different from that for performing the deposition process of the metal layer, the impurity residual etched away from the substrate does not contaminate the wall of the tool system for performing the deposition process. Also, before the deposition process is performed a soft clean with the operation power smaller than that of the dry clean process is performed to remove the possible oxide generated during the transferring procedure so that the surface of the substrate can be completely cleaned.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A method for forming a metal silicide over a substrate, comprising:
performing a fluorine-containing plasma treatment on the substrate to remove a plurality of residual over the substrate, wherein the fluorine-containing plasma treatment is performed in a first tool system;
breaking a vacuum system of the first tool system;
transferring the substrate from the first tool system into a second tool system; and
forming a metal silicide layer over the substrate in the second tool system.

2. The method of claim 1, wherein, before the metal silicide layer is formed, a soft clean process is performed on the substrate.

3. The method of claim 2, wherein the soft clean process is performed by using an inert-gas plasma.

4. The method of claim 3, wherein the inert-gas plasma includes an argon-gas plasma.

5. The method of claim 2, wherein the soft clean process is performed in the second tool system.

6. The method of claim 1, wherein the fluorine-containing plasma treatment is selected from a group consisting of NF₃ plasma, NF₃/NH₃ plasma, NF₃/H₂ plasma and SF₆/H₂O plasma.

7. The method of claim 1, wherein the fluorine-containing plasma treatment is performed at a pressure of about 30 mTorr with a power of about 20˜300 Watt.

8. The method of claim 1, wherein the flow rate of a fluorine-containing gas of the fluorine-containing plasma treatment is about 5˜25 sccm.

9. The method of claim 1, wherein the metal silicide is made of cobalt silicide.

10. A method for cleaning a surface of a substrate before a silicidation process is performed over the substrate, comprising:
performing a dry clean process in an etching tool system; and
performing a soft clean process in a deposition tool system, wherein the silicidation process is going to be performed on the substrate in the deposition tool system.

11. The method of claim 10, wherein the dry clean process is performed by a fluorine-containing plasma.

12. The method of claim 11, wherein the fluorine-containing plasma is selected from a group consisting of NF₃ plasma, NF₃/NH₃ plasma, NF₃/H₂ plasma and SF₆/H₂O plasma.

13. The method of claim 11, wherein the fluorine-containing plasma is performed at a pressure of about 30 mTorr with a power of about 20˜300 Watt.

14. The method of claim 11, wherein the flow rate of a fluorine-containing gas of the fluorine-containing plasma is about 5˜25 sccm.

15. The method of claim 10, before the soft clean process and after the dry clean process, further comprising:
breaking a vacuum system of the etching tool system; and
transferring the substrate from the etching tool system into the deposition tool system.
